(19) United States
(12) Patent Application Publication
(10) Pub. No.: US 2024/0210478 A1
(43) Pub. Date: Jun. 27, 2024

(54) APPARATUS AND METHOD FOR MANAGING BATTERY

(71) Applicant: LG ENERGY SOLUTION, LTD., Seoul (KR)

(72) Inventors: Seo-Young YOON, Daejeon (KR); Soon-Ju CHOI, Daejeon (KR); Soon-Hyung CHOI, Daejeon (KR); Dae-Soo KIM, Daejeon (KR); Young-Deok KIM, Daejeon (KR)

(21) Appl. No.: 18/395,227

(22) Filed: Dec. 22, 2023

(30) Foreign Application Priority Data
Dec. 26, 2022 (KR) 10-2022-0185033
Dec. 26, 2022 (KR) 10-2022-0185081
Dec. 28, 2022 (KR) 10-2022-0187182
Sep. 12, 2023 (KR) 10-2023-0121415

(51) Int. Cl. G01R 31/367; B60L 58/12; G01R 31/388; H01M 10/48

(52) U.S. Cl. CPC G01R 31/367; B60L 58/12; G01R 31/388; H01M 10/48; H01M 2220/20

(57) ABSTRACT

An apparatus for managing a battery according to one aspect of the present disclosure may include a profile obtaining unit configured to obtain a measurement full-cell profile indicating a corresponding relationship between voltage and capacity of a battery; a profile determining unit configured to determine whether or not to divide the measurement full-cell profile into a plurality of sections according to a predetermined reference, adjust a preset reference positive electrode profile and a preset reference negative electrode profile to correspond to the measurement full-cell profile or the plurality of sections according to whether the measurement full-cell profile is divided, and generate an adjusted positive electrode profile and an adjusted negative electrode profile according to the adjustment result; and a control unit configured to determine a diagnostic factor for the battery from at least one of the adjusted positive electrode profile and the adjusted negative electrode profile.

### CROSS-REFERENCE TO RELATED APPLICATIONS

The present application claims priority to Korean Patent Application No. 10-2022-0185033 and No. 10-2022-0185081 filed on Dec. 26, 2022 in the Republic of Korea, Korean Patent Application No. 10-2022-0187182 filed on Dec. 28, 2022 in the Republic of Korea and Korea Patent Application No. 10-2023-0121415 filed on Sep. 12, 2023 in the Republic of Korea, the disclosures of which are incorporated herein by reference.

### TECHNICAL FIELD

The present disclosure relates to an apparatus and method for managing a battery, and more particularly, to an apparatus and method for managing a battery, which estimates a positive electrode profile and a negative electrode profile of a battery.

### BACKGROUND

Recently, the demand for portable electronic products such as notebook computers, video cameras and portable telephones has increased sharply, and electric vehicles, energy storage batteries, robots, satellites and the like have been developed in earnest. Accordingly, high-performance batteries allowing repeated charging and discharging are being actively studied.

Batteries commercially available at present include nickel-cadmium batteries, nickel hydrogen batteries, nickel-zinc batteries, lithium batteries, and the like. Among them, the lithium batteries are in the limelight since they have almost no memory effect compared to nickel-based batteries and also have very low self-charging rate and high energy density.

A lot of research is being conducted on these batteries in terms of high-capacity and high-density, but the aspect of improving lifespan and safety is also important. In order to improve the safety of the battery, the current state of the battery must be accurately diagnosed.

In order to most accurately diagnose the current state of the battery, the positive electrode profile and the negative electrode profile of the battery must be secured and analyzed separately. However, since disassembly and assembly of the already manufactured battery are virtually impossible, the positive electrode profile and the negative electrode profile of the manufactured battery cannot be measured directly. Therefore, in order to diagnose the state of the battery more accurately, a new technology or method that can accurately estimate the positive electrode profile and the negative electrode profile of the battery is desired.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

The present disclosure is designed to solve the problems of the related art, and therefore the present disclosure is directed to providing an apparatus and method for managing a battery that can accurately estimate the positive electrode profile and the negative electrode profile corresponding to the battery.

These and other objects and advantages of the present disclosure may be understood from the following detailed description and will become more fully apparent from the exemplary embodiments of the present disclosure. Also, it will be easily understood that the objects and advantages of the present disclosure may be realized by the means shown in the appended claims and combinations thereof.

An apparatus for managing a battery according to one aspect of the present disclosure may comprise a profile obtaining unit configured to obtain a measurement full-cell profile indicating a corresponding relationship between voltage and capacity of a battery; a profile determining unit configured to determine whether or not to divide the measurement full-cell profile into a plurality of sections according to a predetermined reference, adjust a preset reference positive electrode profile and a preset reference negative electrode profile to correspond to the measurement full-cell profile or the plurality of sections according to whether the measurement full-cell profile is divided, and generate an adjusted positive electrode profile and an adjusted negative electrode profile according to the adjustment result; and a control unit configured to determine a diagnostic factor for the battery from at least one of the adjusted positive electrode profile and the adjusted negative electrode profile.

The profile obtaining unit may be configured to further obtain a full-cell differential profile corresponding to the measurement full-cell profile and indicating a corresponding relationship between capacity and differential voltage.

The profile determining unit may be configured to divide the measurement full-cell profile into the plurality of sections based on at least one of a plurality of peaks included in the full-cell differential profile.

The profile determining unit may be configured to divide the measurement full-cell profile into the plurality of sections based on capacities of the plurality of peaks included in the full-cell differential profile.

The profile determining unit may be configured to generate the adjusted positive electrode profile and the adjusted negative electrode profile corresponding to each of the plurality of sections by adjusting the reference positive electrode profile and the reference negative electrode profile to correspond to each of the plurality of sections.

The profile determining unit may be configured to generate a plurality of adjusted positive electrode profiles such that an end point of the adjusted positive electrode profile for a previous section is the same as a start point of the adjusted positive electrode profile for a next section, and generate a plurality of adjusted negative electrode profiles such that an end point the adjusted negative electrode profile for the previous section is the same as the start point of the adjusted negative electrode profile for the next section.

The profile determining unit may be configured to divide the measurement full-cell profile into the plurality of sections based on a plurality of reference peaks included in the full-cell differential profile.

The profile determining unit may be configured to set a weight for each of the plurality of sections and adjust the reference positive electrode profile and the reference negative electrode profile based on the weight to correspond to the measurement full-cell profile.

The profile determining unit may be configured to set the weight for a target section containing at least one of the plurality of target peaks included in the full-cell differential profile to be larger than the weight for the remaining sections.

The profile determining unit may be configured to generate a comparison full-cell profile based on the adjusted positive electrode profile and the adjusted negative electrode profile, and adjust the reference positive electrode profile and the reference negative electrode profile such that as the section has a larger set weight, an error rate between the comparison full-cell profile and the measurement full-cell profile is lowered.

The profile obtaining unit may be configured to obtain at least one of a positive electrode differential profile corresponding to the reference positive electrode profile and a negative electrode differential profile corresponding to the reference negative electrode profile as an electrode differential profile.

The profile determining unit may be configured to divide a corresponding reference electrode profile among the reference positive electrode profile and the reference negative electrode profile into a plurality of electrode sections based on at least one of a plurality of electrode peaks included in the electrode differential profile, and adjust the reference positive electrode profile and the reference negative electrode profile to correspond to the measurement full-cell profile, while adjusting each of the plurality of electrode sections.

The profile determining unit may be configured to independently adjust each of the plurality of electrode sections.

When the positive electrode differential profile is included in the electrode differential profile, the profile determining unit may be configured to divide the reference positive electrode profile into a plurality of positive electrode sections based on at least one of the plurality of positive electrode peaks included in the positive electrode differential profile.

When the negative electrode differential profile is included in the electrode differential profile, the profile determining unit may be configured to divide the reference negative electrode profile into a plurality of negative electrode sections based on at least one of the plurality of negative electrode peaks included in the negative electrode differential profile.

A battery pack according to another aspect of the present disclosure may comprise the apparatus for managing a battery according to the present disclosure.

A vehicle according to still another aspect of the present disclosure may comprise the apparatus for managing a battery according to the present disclosure.

A method for managing a battery according to still another aspect of the present disclosure may comprise a profile obtaining step of obtaining a measurement full-cell profile indicating a corresponding relationship between voltage and capacity of a battery; a profile adjusting step of determining whether or not to divide the measurement full-cell profile into a plurality of sections according to a predetermined reference and adjusting a preset reference positive electrode profile and a preset reference negative electrode profile to correspond to the measurement full-cell profile or the plurality of sections according to whether the measurement full-cell profile is divided; a profile generating step of generating an adjusted positive electrode profile and an adjusted negative electrode profile according to the adjustment result; and a factor determining step of determining a diagnostic factor for the battery from at least one of the adjusted positive electrode profile and the adjusted negative electrode profile.

According to one aspect, an apparatus for managing a battery is provided. The apparatus may include a profile obtaining unit, a profile determining unit, and a control unit.

The profile obtaining unit may be configured to obtain a first profile, and the first profile may be based on a voltage value of the battery and a capacity value of the battery. The profile determining unit may be configured to: determine whether a first condition is satisfied; upon determining the first condition is satisfied, divide the first profile into a plurality of sections; adjust a first reference profile based on the first profile or the plurality of section to generate a second profile. The control unit may be configured to determine a diagnostic factor based on the second profile.

Any of the apparatus described herein may include nay of the following features. The profile determining unit may be configured to adjust a second reference profile based on the first profile or the plurality of sections to generate a third profile. The second profile may be an adjusted positive electrode profile. The third profile may be an adjusted negative electrode profile. The profile obtaining unit may be further configured to, upon determining the first condition is satisfied, obtain a differential profile corresponding to the first profile. The profile determining unit is configured to divide the first profile into the plurality of sections based on a rate of voltage change in the differential profile. The profile determining unit may be configured to divide the first profile into the plurality of sections based on capacity values associated with the differential profile. The profile determining unit may be configured to generate the second profile and the third profile based on the plurality of sections. The profile determining unit may be configured to generate a plurality of adjusted second profiles. A first point value of a first one of the plurality of adjusted second profiles may correspond to a second point value of a second one of the plurality of adjusted second profiles adjacent to the first one of the plurality of adjusted second profiles. The profile determining unit may be configured to generate a plurality of adjusted third profiles. A third point value of the first one of the plurality of adjusted third profiles may correspond to a fourth point value of a second one of the plurality of adjusted third profiles adjacent to the first one of the plurality of adjusted third profiles. The profile determining unit may be configured to: determine an adjustment factor for each of the plurality of sections; and adjust the first reference profile and the second reference profile based on the adjustment factor. The profile determining unit may be configured to determine a first adjustment factor for a first section of the plurality of sections and a second adjustment factor for a second section of the plurality of sections. The first section of the plurality of sections may be a target section in the differential profile corresponding to the first profile. The first adjustment factor is greater than the second adjustment factor. The profile determining unit may be configured to generate a comparison profile based on the second profile and the third profile. The first reference profile and the second reference profile may be adjusted to generate the comparison profile with minimized profile characteristic difference from the first profile. The profile obtaining unit may be configured to obtain at least one of a first differential profile corresponding to the first reference profile or a second differential profile corresponding to the second reference profile. The profile determining unit may be configured to: divide at least one of the first reference profile or the second reference profile into a plurality of electrode sections based on capacity values associated with a corresponding differential profile; and adjust at least one of the first reference profile or the second reference profile to correspond to the first profile by adjusting at least one of the plurality of electrode sections. The profile determining unit may be configured to adjust each of the plurality of electrode sections. The profile determining unit may be configured to divide the first reference profile into a plurality of first electrode sections based on at least one of peaks of the first differential profile. The profile determining unit may be configured to divide the second reference profile into a plurality of second electrode sections based on at least one of peaks in the second differential profile.

According to one aspect, a battery pack may be provided. The battery pack may include the apparatus for managing the battery described in the foregoing disclosure.

According to one aspect, a vehicle is provided. The vehicle may include the apparatus for managing the battery described in the foregoing disclosure.

According to one aspect, a method is provided for managing a battery. The method may include: obtaining a first profile, the first profile being based on a voltage value of the battery and a capacity value of the battery; determining whether a first condition is satisfied; upon determining the first condition is satisfied, dividing the first profile into a plurality of sections; adjusting a first reference profile based on the first profile to generate a second profile; and determining a diagnostic factor based on the second profile.

Any of the methods described here may include any of the following steps or features. The method may further include adjusting a second reference profile based on the first profile or the plurality of sections to generate a third profile. The second profile may be a positive electrode profile. The third profile may be a negative electrode profile.

According to one aspect of the present disclosure, the apparatus for managing a battery has an advantage of estimating the positive electrode profile and the negative electrode profile of a battery, which cannot be measured directly, by adjusting the reference positive electrode profile and the reference negative electrode profile.

Additionally, because the apparatus for managing a battery can determine a diagnostic factor indicating the current state of the battery, the current state of the battery can be diagnosed based on the diagnostic factor. In other words, the apparatus for managing a battery has an advantage of determining diagnostic factors that can diagnose the current state of the battery in a non-destructive manner.

The effects of the present disclosure are not limited to the effects mentioned above, and other effects not mentioned will be clearly understood by those skilled in the art from the description of the claims.

### BRIEF DESCRIPTION OF DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawings.

FIG. 1 is a diagram schematically showing an apparatus for managing a battery according to an embodiment of the present disclosure.

FIG. 2 is a diagram showing a measurement full-cell profile according to an embodiment of the present disclosure.

FIG. 3 is a diagram showing a reference positive electrode profile, a reference negative electrode profile, and a reference full-cell profile according to an embodiment of the present disclosure.

FIG. 4 is a diagram showing a measurement full-cell profile a the reference full-cell profile according to an embodiment of the present disclosure.

FIG. 5 is a diagram showing a reference full-cell profile and a comparison full-cell profile according to an embodiment of the present disclosure.

FIG. 6 is a diagram showing a full-cell differential profile according to an embodiment of the present disclosure.

FIG. 7 is a diagram showing a measurement full-cell profile and a plurality of sections according to an embodiment of the present disclosure.

FIG. 8 is a diagram showing a measurement full-cell profile and a first comparison full-cell profile according to an embodiment of the present disclosure.

FIG. 9 is a diagram showing a full-cell differential profile according to an embodiment of the present disclosure.

FIG. 10 is a diagram showing a measurement full-cell profile and a plurality of sections according to an embodiment of the present disclosure.

FIG. 11 is a diagram showing a measurement full-cell profile and a second comparison full-cell profile according to an embodiment of the present disclosure.

FIG. 12 is a diagram showing a positive electrode differential profile according to an embodiment of the present disclosure.

FIG. 13 is a diagram showing a negative electrode differential profile according to an embodiment of the present disclosure.

FIG. 14 is a diagram showing a reference positive electrode profile and a reference negative electrode profile according to an embodiment of the present disclosure.

FIG. 15 is a diagram showing a measurement full-cell profile and a third comparison full-cell profile according to an embodiment of the present disclosure.

FIG. 16 is a diagram showing an exemplary configuration of a battery pack according to an embodiment of the present disclosure.

FIG. 17 is a diagram schematically showing a vehicle according to an embodiment of the present disclosure.

FIG. 18 is a diagram schematically showing a method for managing a battery according to an embodiment of the present disclosure.

### DETAILED DESCRIPTION

It should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

Therefore, the description proposed herein is just a preferable example for the purpose of illustrations only, not intended to limit the scope of the disclosure, so it should be understood that other equivalents and modifications could be made thereto without departing from the scope of the disclosure.

Additionally, in describing the present disclosure, when it is deemed that a detailed description of relevant known elements or functions renders the key subject matter of the present disclosure ambiguous, the detailed description is omitted herein.

The subject matter of the present description will now be described more fully hereinafter with reference to the accompanying drawings, which form a part thereof, and which show, by way of illustration, specific exemplary embodiments. An embodiment or implementation described herein as “exemplary” is not to be construed as preferred or advantageous, for example, over other embodiments or implementations; rather, it is intended to reflect or indicate that the embodiment(s) is/are “example” embodiment(s). Subject matter can be embodied in a variety of different forms and, therefore, covered or claimed subject matter is intended to be construed as not being limited to any exemplary embodiments set forth herein; exemplary embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware, or any combination thereof (other than software per se). The following detailed description is, therefore, not intended to be taken in a limiting sense.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of exemplary embodiments in whole or in part.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. Both the foregoing general description and the following detailed description are exemplary and explanatory only and are not restrictive of the features, as claimed.

In this disclosure, the term “based on” means “based at least in part on.” The terms including the ordinal number such as “first”, “second” and the like, may be used to distinguish one element from another among various elements, but not intended to limit the elements by the terms. The singular forms “a,” “an,” and “the” include plural referents unless the context dictates otherwise. The term “exemplary” is used in the sense of “example” rather than “ideal.” The term “or” is meant to be inclusive and means either, any, several, or all of the listed items. The terms “comprises,” “comprising,” “includes,” “including,” or other variations thereof, are intended to cover a nonexclusive inclusion such that a process, method, or product that comprises a list of elements does not necessarily include only those elements, but may include other elements not expressly listed or inherent to such a process, method, article, or apparatus. Relative terms, such as, “substantially” and “generally,” are used to indicate a possible variation of ±5% of a stated or understood value.

In addition, throughout the specification, when a portion is referred to as being “connected” or “coupled” to another portion, it is not limited to the case that they are “directly connected” or “directly coupled”, but it also includes the case where they are “indirectly connected” or “indirectly coupled” with one or more elements being arranged between them.

Hereinafter, preferred embodiments of the present disclosure will be described in detail with reference to the accompanying drawings.

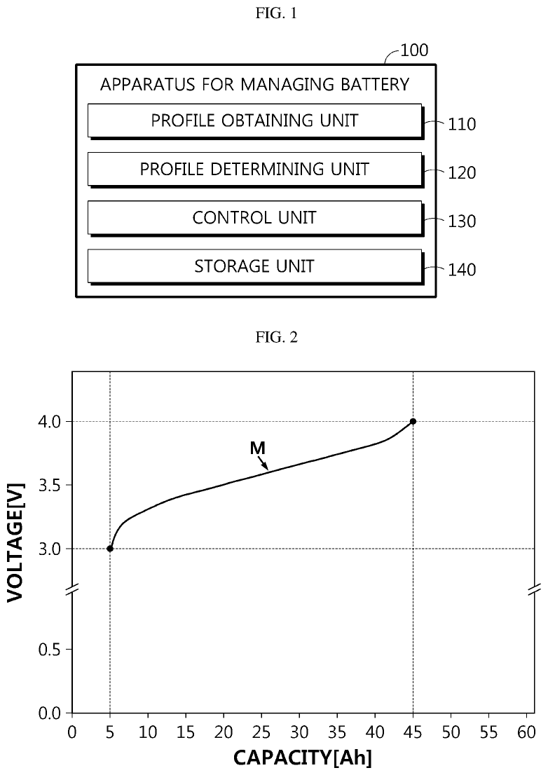

FIG. 1 is a diagram schematically showing an apparatus 100 for managing a battery according to an embodiment of the present disclosure.

Referring to FIG. 1, the apparatus 100 for managing a battery may include a profile obtaining unit 110, a profile determining unit 120, and a control unit 130.

Here, the battery may refer to an independent cell that has a negative terminal and a positive terminal that may be physically separated. For example, the battery may be a lithium-ion battery or a lithium polymer battery. Additionally, the battery may include a cylindrical type, a prismatic type, or a pouch type. Additionally, the battery may referred to a battery bank, a battery module, or a battery pack in which a plurality of cells may be connected in series and/or parallel. Hereinafter, for convenience of explanation, the battery may also be referred to as one independent cell.

The profile obtaining unit 110 may be configured to obtain a measurement full-cell profile M indicating a corresponding relationship between voltage and capacity of the battery. For example, the measurement full-cell profile M may represent a capacity-voltage relationship of the battery.

For example, the measurement full-cell profile M may be a profile that represents a corresponding relationship between voltage (V) and capacity (Q) when the SOC of the battery is charged from 0% to 100%.

For example, there is no special limitation on the C-rate in charging or discharging of the battery to generate the measurement full-cell profile M. However, preferably, in order to obtain more accurate measurement full-cell profile M and full-cell differential profile D, the battery should be charged or discharged at a low rate. For example, in the process of charging or discharging a battery at 0.05 C, a measurement full-cell profile M may be generated.

For example, the profile obtaining unit 110 may directly receive the measurement full-cell profile M of the battery from an outside source. For example, the outside source may be a server, a cloud server, a network, etc. That is, the profile obtaining unit 110 may obtain or receive the measurement full-cell profile M from the outside source via one or more wires and/or wirelessly.

In one embodiment, the profile obtaining unit 110 may receive battery information about the voltage and capacity of the battery. Further, the profile obtaining unit 110 may obtain the measurement full-cell profile M by generating the measurement full-cell profile M based on the received battery information.

FIG. 2 is a diagram showing a measurement full-cell profile M according to an embodiment of the present disclosure.

For example, as shown in FIG. 2, the measurement full-cell profile M can be expressed as a two-dimensional X-Y graph with the X-axis set to capacity [Ah] and the Y-axis set to voltage [V].

The profile obtaining unit 110 may be connected to communicate with the control unit 130. For example, the profile obtaining unit 110 may be connected to the control unit 130 via wires and/or wirelessly. The profile obtaining unit 110 may transmit the obtained measurement full-cell profile M to the profile determining unit 120.

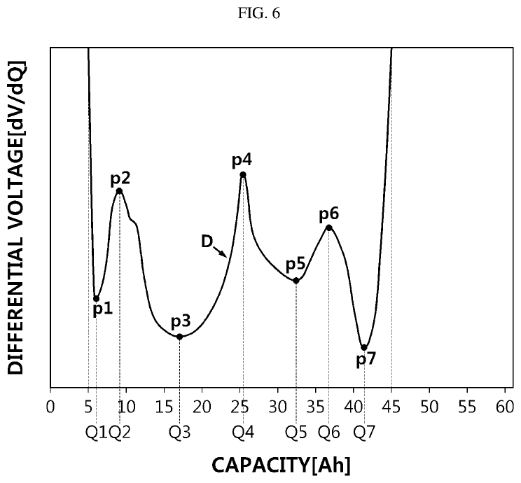

The profile determining unit 120 may be configured to determine whether or not to divide the measurement full-cell profile M into a plurality of sections according to a predetermined criterion or specification. The predetermined criterion may be one or more conditions. For example, the one or more conditions may include presence of differential data corresponding to the measurement full-cell profile M or one or more voltage or capacity characteristics of the measurement full-cell profile M, but are not limited thereto. The differential data may be, for example, the full-cell differential profiles shown in FIGS. 6, 9, 12, and 13. Accordingly, the profile determining unit 120 may determine whether or not to divide the measurement full-cell profile M based on satisfying the one or more conditions.

In one embodiment, the profile determining unit 120 may determine whether or not to divide the measurement full-cell profile M into a plurality of sections according to a predetermined capacity criterion or characteristic.

That is, the profile determining unit 120 may divide the entire capacity section (or capacity value section) of the measurement full-cell profile M into a plurality of sections based on a capacity value determined according to a predetermined capacity criterion or characteristic.

The profile determining unit 120 may be configured to adjust a preset reference positive electrode profile Rp and a preset reference negative electrode profile Rn to correspond to the measurement full-cell profile M or the plurality of sections, depending on whether the measurement full-cell profile M is divided.

For example, the preset reference positive electrode profile Rp may be a profile representing a correspondence relationship between the capacity and voltage of the preset reference positive electrode cell to correspond to the positive electrode of the battery. For example, the reference positive electrode cell may be a positive electrode coin half-cell or a positive electrode of a three-electrode cell. Additionally, the reference negative electrode profile Rn may be a profile representing a correspondence relationship between the capacity and voltage of the preset reference negative electrode cell to correspond to the negative electrode of the battery. For example, the reference negative electrode cell may be a negative electrode coin half-cell or a negative electrode of a three-electrode cell.

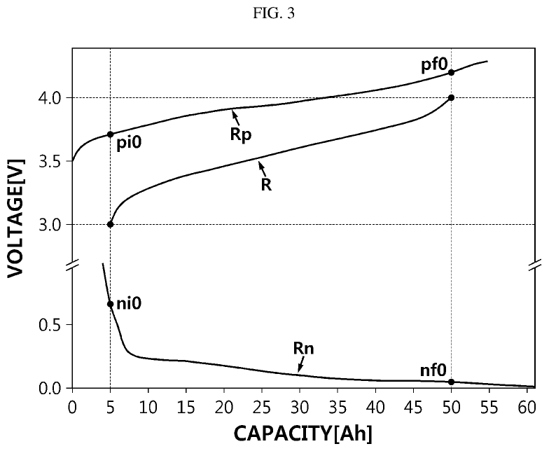

FIG. 3 is a diagram showing a reference positive electrode profile Rp, a reference negative electrode profile Rn, and a reference full-cell profile R according to an embodiment of the present disclosure.

As shown in FIG. 3, on the reference positive electrode profile Rp, a positive electrode participation start point may be pi0, and a positive electrode participation end point may be pf0. On the reference negative electrode profile Rn, the negative electrode participation start point may be ni0, and the negative electrode participation end point may be nf0. The reference full-cell profile R may be a reference for a capacity value and can be expressed as the difference between the positive electrode potential of the reference positive electrode profile Rp and the negative electrode potential of the reference negative electrode profile Rn.

In one embodiment, depending on whether the measurement full-cell profile M is divided, the adjustment target of the reference positive electrode profile Rp and the reference negative electrode profile Rn may be different between the entire section (e.g., the entire length of the profile M on the capacity axis) of the measurement full-cell profile M and each section (e.g., each section on the capacity axis) of the measurement full-cell profile M.

For example, when the measurement full-cell profile M is not divided into a plurality of sections, the profile determining unit 120 may adjust the reference positive electrode profile Rp and the reference negative electrode profile Rn to correspond to the entire section (e.g., the entire section of the profile M on the capacity axis) of the measurement full-cell profile M. Here, one adjustment result for the reference positive electrode profile Rp and the reference negative electrode profile Rn can be derived.

In one embodiment, the profile determining unit 120 may generate a plurality of comparison full-cell profiles S by shifting the reference positive electrode profile Rp and the reference negative electrode profile Rn or performing capacity scaling thereto. Further, the profile determining unit 120 may specify or identify one or more of the plurality of comparison full-cell profiles S having the minimum error (or minimum difference) in comparison with the measurement full-cell profile M. Also, the adjusted positive electrode profile Rp′ and the adjusted negative electrode profile Rn′ corresponding to the specified or identified comparison full-cell profile S can be determined.

Alternatively or additionally, when the measurement full-cell profile M is divided into a plurality of sections, the profile determining unit 120 may adjust the reference positive electrode profile Rp and the reference negative electrode profile Rn to correspond to each of the plurality of sections of the measurement full-cell profile M. If the measurement full-cell profile M is divided into n sections (where n is a natural number), the reference positive electrode profile Rp and the reference negative electrode profile Rn can be adjusted to correspond to each of the n sections. That is, n adjustment results for the reference positive electrode profile Rp and the reference negative electrode profile Rn can be derived.

In one embodiment, the profile determining unit 120 may generate a plurality of comparison full-cell profiles S by shifting the reference positive electrode profile Rp and the reference negative electrode profile Rn or performing capacity scaling thereto. Further, the profile determining unit 120 may specify or identify one or more of the plurality of comparison full-cell profiles S having the minimum error (or minimum difference) in comparison with each section of the measurement full-cell profile M. Also, the adjusted positive electrode profile Rp′ and the adjusted negative electrode profile Rn′ corresponding to the one or more comparison full-cell profile S specified or identified for each section of the measurement full-cell profile M can be determined.

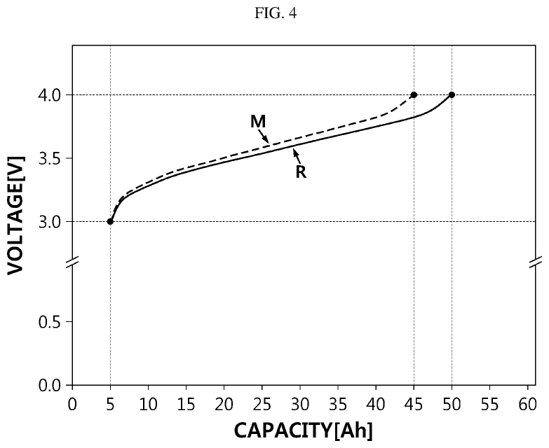

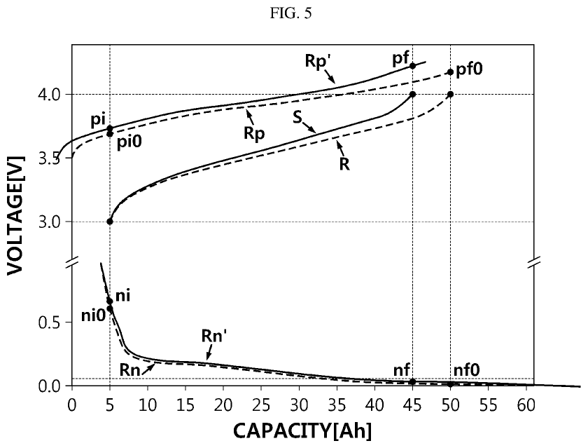

FIG. 4 is a diagram showing the measurement full-cell profile M and the reference full-cell profile R according to an embodiment of the present disclosure.

In the embodiment of FIG. 4, the reference full-cell profile R and the measurement full-cell profile M may be different so that they do not correspond to each other. For example, the voltage sections (e.g., voltage values on the voltage axis) of the measurement full-cell profile M and the reference full-cell profile R may be the same as 3.0 [V] to 4.0 [V], but the capacity section (e.g., capacity values on the capacity axis) of the measurement full-cell profile M may be 5 [Ah] to 45 [Ah], and the capacity section of the reference full-cell profile R may be 5 [Ah] to 50 [Ah]. Since the reference full-cell profile R and the measurement full-cell profile M are different, the profile determining unit 120 may adjust the reference positive electrode profile Rp and the reference negative electrode profile Rn to correspond to the measurement full-cell profile M.

The profile determining unit 120 may be configured to generate an adjusted positive electrode profile Rp′ and an adjusted negative electrode profile Rn′ according to the adjustment result.

In one embodiment, the adjusted positive electrode profile Rp′ is the result of adjusting the reference positive electrode profile Rp, and the adjusted negative electrode profile Rn′ is the result of adjusting the reference negative electrode profile Rn. In other words, the comparison full-cell profile S is specified or identified according to the adjustment result of the reference positive electrode profile Rp and the reference negative electrode profile Rn, and the basis of the comparison full-cell profile S is the adjusted positive electrode profile Rp′ and the adjusted negative electrode profile Rn′. Therefore, the adjusted positive electrode profile Rp′ and the adjusted negative electrode profile Rn′ is accurately estimated to be the positive electrode profile and the negative electrode profile of the battery.

FIG. 5 is a diagram showing the reference full-cell profile R and the comparison full-cell profile S according to an embodiment of the present disclosure.

For example, as shown in FIG. 5, the reference positive electrode profile Rp can be adjusted to the adjusted positive electrode profile Rp′, and the reference negative electrode profile Rn can be adjusted to the adjusted negative electrode profile Rn′. In other words, the reference full-cell profile R can be adjusted to generate or obtain the comparison full-cell profile S. In one embodiment, the positive electrode participation start point pi0 of the reference positive electrode profile Rp can be adjusted to the positive electrode participation start point pi of the adjusted positive electrode profile Rp′, and the positive electrode participation end point pf0 of the reference positive electrode profile Rp can be adjusted to the positive electrode participation end point pf of the adjusted positive electrode profile Rp′. The negative electrode participation start point ni0 of the reference negative electrode profile Rn can be adjusted to the negative electrode participation start point ni of the adjusted negative electrode profile Rn′, and the negative electrode participation end point nf0 of the reference negative electrode profile Rn can be adjusted to the negative electrode participation end point nf of the adjusted negative electrode profile Rn′.

The control unit 130 may be configured to determine a diagnostic factor for the battery from at least one of the adjusted positive electrode profile Rp′ and the adjusted negative electrode profile Rn′.

In one embodiment, the diagnostic factor may include at least one of the positive electrode factor or the negative electrode factor. That is, the control unit 130 may be configured to determine the positive electrode factor for the battery from the adjusted positive electrode profile Rp′. Additionally, the control unit 130 may be configured to determine the negative electrode factor for the battery from the adjusted negative electrode profile Rn′.

For example, the positive electrode factor may include the positive electrode participation start point pi, the positive electrode participation end point pf, and the positive electrode change rate ps.

The positive electrode participation start point pi is the start point of the adjusted positive electrode profile Rp′. For example, in the embodiment of FIG. 5, the positive electrode participation start point pi is a point corresponding to capacity 5 [Ah] in the adjusted positive electrode profile Rp′.

The positive electrode participation end point pf is the end point of the adjusted positive electrode profile Rp′. For example, in the embodiment of FIG. 5, the positive electrode participation end point pf is a point corresponding to capacity 45 [Ah] in the adjusted positive electrode profile Rp′.

The positive electrode change rate ps may mean the change rate [%] of the adjusted positive electrode profile Rp′ with respect to the reference positive electrode profile Rp. For example, the positive electrode change rate ps may be the contraction ratio or expansion ratio of the adjusted positive electrode profile Rp′ with respect to the reference positive electrode profile Rp. For example, if the adjusted positive electrode profile Rp′ is 10% shrinkage from the reference positive electrode profile Rp, the positive electrode change rate ps is 90%. Conversely, if the adjusted positive electrode profile Rp′ is 10% extension from the reference positive electrode profile Rp, the positive electrode change rate ps is 110%.

As another example, the negative electrode factor may include the negative electrode participation start point ni, the negative electrode participation end point nf, and the negative electrode change rate ns.

The negative electrode participation start point ni is the start point of the adjusted negative electrode profile Rn′. For example, as shown in FIG. 5, the negative electrode participation start point ni is a point corresponding to capacity 5 [Ah] in the adjusted negative electrode profile Rn′.

The negative electrode participation end point nf is the end point of the adjusted negative electrode profile Rn′. For example, as shown in FIG. 5, the negative electrode participation end point nf is a point corresponding to capacity 45 [Ah] in the adjusted negative electrode profile Rn′.

The negative electrode change rate ns may mean the change rate [%] of the adjusted negative electrode profile Rn′ with respect to the reference negative electrode profile Rn. Specifically, the negative electrode change rate ns may be the contraction ratio or expansion ratio of the adjusted negative electrode profile Rn′ with respect to the reference negative electrode profile Rn. For example, if the adjusted negative electrode profile Rn′ is 10% shrinkage from the reference negative electrode profile Rn, the negative electrode change rate ns is 90%. Conversely, if the adjusted negative electrode profile Rn′ is 10% extension from the reference negative electrode profile Rn, the negative electrode change rate ns is 110%.

The apparatus 100 for managing a battery according to an embodiment of the present disclosure has an advantage of estimating the positive electrode profile and the negative electrode profile of a battery, which cannot be measured directly in a manufactured or assembled battery, by adjusting the reference positive electrode profile Rp and the reference negative electrode profile Rn. Additionally, because the apparatus 100 for managing a battery can determine a diagnostic factor(s), which may indicate the current state of the battery, the current state of the battery can be diagnosed based on the diagnostic factor(s). In other words, the apparatus 100 for managing a battery has an advantage of determining diagnostic factors that can be used to diagnose the current state of the battery in a non-destructive manner.

In one embodiment, the control unit 130 may determine the positive electrode change rate ps as a diagnostic factor. The control unit 130 may compare the determined positive electrode change rate ps and a reference rate preset for the battery. Additionally, the control unit 130 may diagnose the state of the battery based on the ratio difference between the positive electrode change rate ps and the reference rate. If the calculated ratio difference is greater than or equal to a threshold value, the control unit 130 may diagnose the state of the battery to be in an abnormal or deteriorated state. Conversely, if the ratio difference is less than the threshold value, the control unit 130 may diagnose the state of the battery as a normal state.

In one embodiment, the control unit 130 may determine the positive electrode change rate ps for a plurality of batteries as a diagnostic factor. The control unit 130 may diagnose the relative degree of degradation for the plurality of batteries by comparing the magnitude of the determined plurality of positive electrode change rates ps. For example, the control unit 130 may diagnose that as the determined positive electrode change rate ps increases, the of degradation state of the battery may worsen.

In the above, an embodiment in which the control unit 130 diagnoses the state of the battery using the positive electrode change rate ps has been described, but it should be noted that the state of the battery can be diagnosed based on one or more of the diagnostic factors.

Additionally, the control unit 130 may diagnose the state of the battery by combining diagnosis results based on a plurality of diagnostic factors. For example, the control unit 130 may diagnose the state of the battery based on the majority of diagnosis results among the plurality of diagnostic factors.

Further, the control unit 130 included in the apparatus 100 for managing a battery may include a processor, an application-specific integrated circuit (ASIC), other chipset, a logic circuit, a register, a communication modem, a data processing device, etc. known in the art to execute various control logics performed in the present disclosure. Also, when the control logic is implemented as software, the control unit 130 may be implemented as a set of program modules. At this time, the program module may be stored in the memory and executed by the control unit 130. The memory may be inside or outside the control unit 130 and may be connected to the control unit 130 by various well-known means.

In addition, the apparatus 100 for managing a battery may further include a storage unit 140. The storage unit 140 may store data necessary for operation and function of each component of the apparatus 100 for managing a battery, data generated in the process of performing the operation or function, or the like. The storage unit 140 is not particularly limited in its kind as long as it is a known information storage means that can record, erase, update and read data. As an example, the information storage means may include RAM, flash memory, ROM, EEPROM, registers, and the like. In addition, the storage unit 140 may store program codes in which processes executable by the control unit 130 are defined.

The apparatus 100 disclosed in connection with embodiments of FIGS. 1-18 and the various elements therein comprised, which enable the implementation of methods and processes in accordance with the present disclosure, may be implemented by a processor using a plurality of microprocessors executing software or firmware, or may be implemented using one or more application specific integrated circuits (ASICs) and related software. In other examples, the apparatus 100 the various elements therein comprised, which enable the implementation of methods and processes in connection with embodiments of FIGS. 1-18, may be implemented using a combination of ASICs, discrete electronic components (e.g., transistors), and microprocessors. In some embodiments, components shown as separate may be replaced by a single component. In addition, some of the components displayed may be additional, or may be replaced by other components.

For example, the storage unit 140 may store the reference positive electrode profile Rp, the reference negative electrode profile Rn, the reference full-cell profile R, the measurement full-cell profile M, the adjusted positive electrode profile Rp′, the adjusted negative electrode profile Rn′, the comparison full-cell Profile S, the positive electrode factor, the negative electrode factor, etc.

Referring to FIGS. 6 to 8, the profile determining unit 120 may adjust the reference positive electrode profile Rp and the reference negative electrode profile Rn in accordance with an embodiment of the present disclosure.

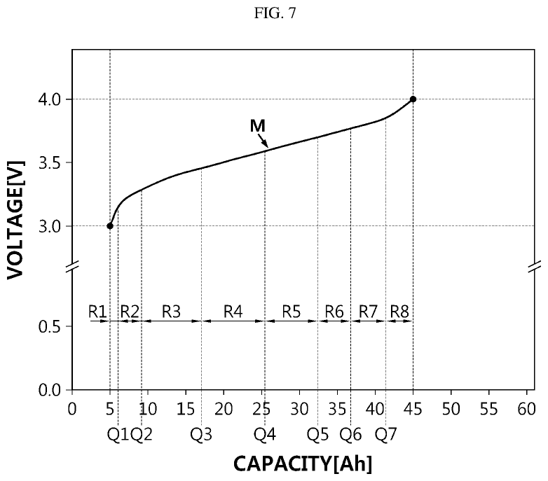

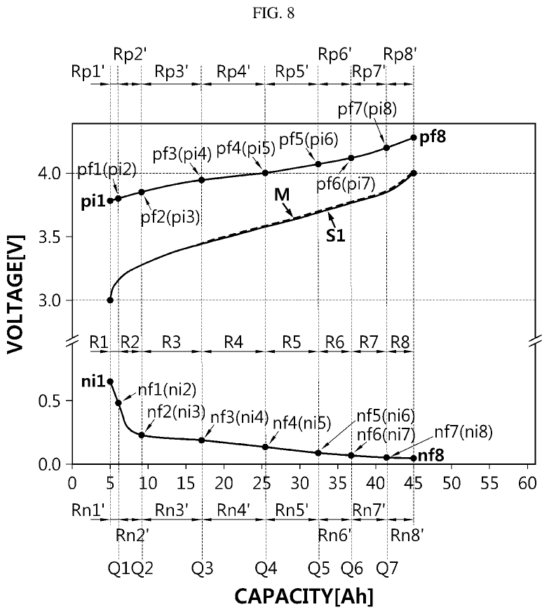

FIG. 6 is a diagram showing a full-cell differential profile D according to an embodiment of the present disclosure. FIG. 7 is a diagram showing the measurement full-cell profile M and a plurality of sections according to an embodiment of the present disclosure. FIG. 8 is a diagram showing the measurement full-cell profile M and the first comparison full-cell profile S1 according to an embodiment of the present disclosure.

The profile obtaining unit 110 may be configured to further obtain a full-cell differential profile D that corresponds to the measurement full-cell profile M and indicates the corresponding relationship between capacity and differential voltage.

For example, the full-cell differential profile D is a profile obtained by differentiating the measurement full-cell profile M with respect to capacity. In other words, the full-cell differential profile D is a profile that represents the corresponding relationship between capacity and differential voltage. Here, the differential voltage is a value obtained by differentiating voltage (V) with respect to capacity (Q), and can be expressed as “dV/dQ.”

For example, as shown in FIG. 6, the full-cell differential profile D may be expressed as a two-dimensional X-Y graph with the X-axis set to capacity [Ah] and the Y-axis set to differential voltage [dV/dQ].

For example, the profile obtaining unit 110 may receive the full-cell differential profile D of the battery from an external source. That is, the profile obtaining unit 110 may obtain the full-cell differential profile D by being connected to the outside of the apparatus 100 via one or more wire and/or wirelessly and receiving the full-cell differential profile D.

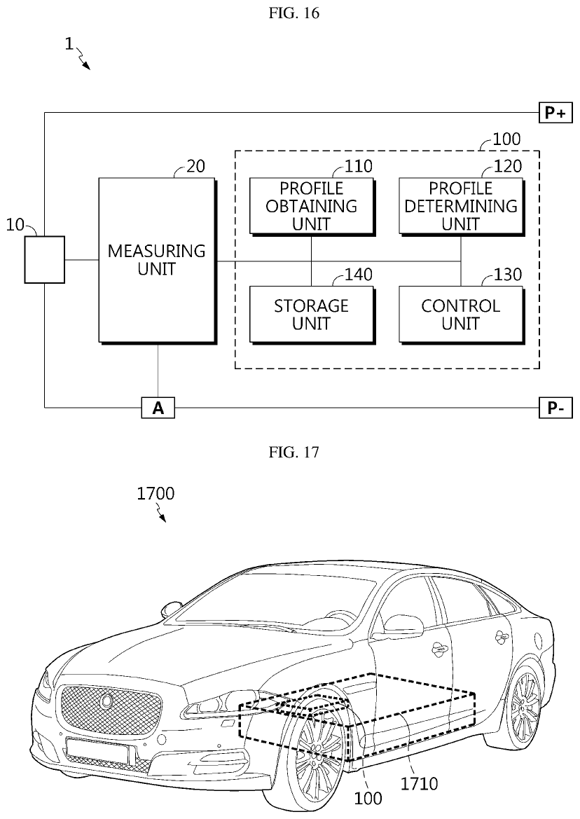

Additionally or alternatively, the profile obtaining unit 110 may generate a full-cell differential profile D based on a received measurement full-cell profile M or a generated measurement full-cell profile M, for example, by a measuring unit 20 shown later in FIG. 16. For example, the profile obtaining unit 110 may obtain the full-cell differential profile D by directly generating the full-cell differential profile D by differentiating the measurement full-cell profile M with respect to capacity.

The profile obtaining unit 110 may transmit the obtained full-cell differential profile D to the profile determining unit 120.

The profile determining unit 120 may be configured to divide the measurement full-cell profile M into a plurality of sections based on at least one of the plurality of peaks included in the full-cell differential profile D.

In one embodiment, each of the peaks p1-p7 may refer to a point corresponding to an inflection point of the measurement full-cell profile M. In other words, each of the peaks p1-p7 may refer to a point in the full-cell differential profile D where the instantaneous rate of change of differential voltage relative to capacity is 0. For example, the maximum and minimum points of the full-cell differential profile D may be determined as peaks, as shown in FIG. 6.

In accordance with FIG. 6, the profile determining unit 120 may determine or identify the first to seventh peaks p1 to p7 in the full-cell differential profile D. Here, the first peak p1, the third peak p3, the fifth peak p5, and the seventh peak p7 are peaks may correspond to the minimum point of the full-cell differential profile D, and the second peak p2, the fourth peak p4, and the sixth peak p6 are peaks may correspond to the maximum point of the full-cell differential profile D.

For example, the profile determining unit 120 may be configured to divide the measurement full-cell profile M into a plurality of sections based on the capacity of the plurality of peaks included in the full-cell differential profile D.

For example, in accordance with FIG. 7, the profile determining unit 120 may divide the measurement full-cell profile M into first to eighth sections R1 to R8 according to the plurality of capacities Q1 to Q7 corresponding to the first to seventh peaks p1 to p7. For example, the first section R1 may be the capacity section of 0 [Ah] to Q1, the second section R2 may be the capacity section of Q1 to Q2, and the third section R3 maybe the capacity section of Q2 to Q3. The fourth section R4 may be the capacity section of Q3 to Q4, the fifth section R5 may be the capacity section of Q4 to Q5, and the sixth section R6 may be the capacity section of Q5 to Q6. The seventh section R7 may be the capacity section of Q6 to Q7, and the eighth section R8 may be the capacity section of Q7 to 45 [Ah].

Additionally, the profile determining unit 120 may be configured to adjust the reference positive electrode profile Rp and the reference negative electrode profile Rn to correspond to each of the plurality of sections. That is, the profile determining unit 120 may be configured to generate an adjusted positive electrode profile and an adjusted negative electrode profile corresponding to each of the plurality of sections.

For example, the reference positive electrode profile Rp and the reference negative electrode profile Rn may be adjusted to correspond to each section of the measurement full-cell profile M.

For example, in accordance with FIG. 7, the profile determining unit 120 may adjust the reference positive electrode profile Rp and the reference negative electrode profile Rn with respect to the first section R1 of the measurement full-cell profile M. The profile determining unit 120 may generated a plurality of comparison full-cell profiles based on a plurality of adjustments performed on the reference positive electrode profile Rp and the reference negative electrode profile Rn. For example, among the plurality of comparison full-cell profiles generated by the profile determining unit 120, the comparison full-cell profile that is most similar to the measurement full-cell profile M (e.g., having the smallest error or difference) in the first section R1 may be specified. Additionally, the profile determining unit 120 may determine the first adjusted positive electrode profile Rp1′ and the first adjusted negative electrode profile Rn1′ corresponding to the comparison full-cell profile that has the smallest difference from the measurement full-cell profile M in the first section R1.

In the same manner, the profile determining unit 120 may determine second to eighth adjusted positive electrode profiles Rp2′ to Rp8′ and second to eighth adjusted negative electrode profiles Rp2′ to Rp8′ for each of the second to eighth sections R2 to R8 of the measurement full-cell profile M.

For example, in accordance with FIG. 8, the first adjusted positive electrode profile Rp1′ and the first adjusted negative electrode profile Rn1′ corresponding to the first section R1 may be determined, and the second adjusted positive electrode profile Rp2′ and the second adjusted negative electrode profile Rn2′ corresponding to the second section R2 may be determined. The third adjusted positive electrode profile Rp3′ and the third adjusted negative electrode profile Rn3′ corresponding to the third section R3 may be determined, and the fourth adjusted positive electrode profile Rp4′ and the fourth adjusted negative electrode profile Rn4′ corresponding to the fourth section R4 may be determined. The fifth adjusted positive electrode profile Rp5′ and the fifth adjusted negative electrode profile Rn5′ corresponding to the fifth section R5 may be determined, and the sixth adjusted positive electrode profile Rp6′ and the sixth adjusted negative electrode profile Rn6′ corresponding to the sixth section R6 may be determined. The seventh adjusted positive electrode profile Rp7′ and the seventh adjusted negative electrode profile Rn7′ corresponding to the seventh section R7 are determined, and the eighth adjusted positive electrode profile Rp8′ and the eighth adjusted negative electrode profile Rn8′ corresponding to the eighth section R8 may be determined.

The control unit 130 may determine the positive electrode factor from each of the plurality of adjusted positive electrode profiles Rp1′ to Rp8′ and determine the negative electrode factor from each of the plurality of adjusted negative electrode profiles Rn1′ to Rn8′. Additionally, the control unit 130 may diagnose the state of the positive electrode of the battery in the corresponding section based on each of the determined plurality of positive electrode factors. Additionally, the control unit 130 may diagnose the state of the negative electrode of the battery in the corresponding section based on each of the determined plurality of negative electrode factors.

Referring to FIG. 8, the control unit 130 may determine the positive electrode participation start points pi1 to pi8, the positive electrode participation end points pf1 to pf8, and the positive electrode change rates ps1 to ps8 of the first to eighth adjusted positive electrode profiles Rp1′ to Rp8′. Likewise, the control unit 130 may determine the negative electrode participation start points ni1 to ni8, the negative electrode participation end points nf1 to nf8, and the negative electrode change rates ns1 to ns8 of the first to eighth adjusted negative electrode profiles Rn1′ to Rn8′.

For example, the control unit 130 may determine the positive electrode deterioration degree for each of the first to eighth sections R1 to R8 based on the plurality of positive electrode change rates ps1 to ps8. For example, the control unit 130 may determine the positive electrode change rate of each of the first to eighth sections R1 to R8 as the positive electrode deterioration degree in the corresponding section. Accordingly, the control unit 130 may be configured to determine the section in which the positive electrode is degraded the most among the first to eighth sections R1 to R8.

Additionally, the control unit 130 may determine the negative electrode degradation degree of each of the first to eighth sections R1 to R8 by considering the plurality of negative electrode change rates ns1 to ns8. For example, the control unit 130 may determine the negative electrode change rate for each of the first to eighth sections R1 to R8 as the negative electrode degradation degree in the corresponding section. Accordingly, the control unit 130 may be configured to determine the section in which the negative electrode is degraded most among the first to eighth sections R1 to R8.

Referring to FIG. 8, the profile determining unit 120 may determine the first comparison full-cell profile S1 corresponding to the measurement full-cell profile based on the first to eighth adjusted positive electrode profiles Rp1′ to Rp8′ and the first to eighth adjusted negative electrode profiles Rn1′ to Rn8′. The control unit 130 may determine the positive electrode participation start point of the battery as pi1 and determine the positive electrode participation end point as pf8. Additionally, the control unit 130 may determine the negative electrode participation start point of the battery as ni1 and determine the negative electrode participation end point as nf8.

For example, the profile determining unit 120 may be configured to generate a plurality of adjusted positive electrode profiles Rp1′ to Rp8′ such that the end point of the adjusted positive electrode profile Rp′ for a previous section is the same as the start point of the adjusted positive electrode profile Rp′ for the next section. Similarly, the profile determining unit 120 may be configured to generate a plurality of adjusted negative electrode profiles Rn1′ to Rn8′ such that the end point of the adjusted negative electrode profile Rn′ for a previous section is the same as the start point of the adjusted negative electrode profile Rn′ for the next section.

For example, since the plurality of adjusted positive electrode profiles Rp1′ to Rp8′ may be determined as the adjusted positive electrode profile Rp′ of the battery as a whole, the plurality of adjusted positive electrode profiles Rp1′ to Rp8′ may be continuous. Likewise, the plurality of adjusted negative electrode profiles Rn1′ to Rn8′ may be continuous because they are determined as the adjusted negative electrode profile Rn′ of the battery as a whole.

For example, in accordance with FIG. 8, the profile determining unit 120 may determine the positive electrode participation end point pf2 of the second adjusted positive electrode profile Rp2′ after setting the positive electrode participation start point pi2 of the second adjusted positive electrode profile Rp2′ to be equal to the positive electrode participation end point pf1 of the first adjusted positive electrode profile Rp1′. Likewise, the profile determining unit 120 may set each of the positive electrode participation start points pi3 to pi8 of the third to eighth adjusted positive electrode profiles Rp3′ to Rp8′ to correspond to each of the positive electrode participation end points pf2 to pf7 of the second to seventh adjusted positive electrode profiles Rp2′ to Rp7′.

In addition, in accordance with FIG. 8, the profile determining unit 120 may determine the negative electrode participation end point nf2 of the second adjusted negative electrode profile Rn2′ after setting the negative electrode participation start point ni2 of the second adjusted negative electrode profile Rn2′ to be identical to the negative electrode participation end point nf1 of the first adjusted negative electrode profile Rn1′. Similarly, the profile determining unit 120 may determine each of the negative electrode participation start points ni3 to ni8 of the third to eighth adjusted negative electrode profiles Rn3′ to Rn8′ to correspond to each of the negative electrode participation end points nf2 to nf7 of the second to seventh adjusted negative electrode profiles Rn2′ to Rn7′.

Also, in accordance with FIG. 8, the control unit 130 may determine the positive electrode participation start point of the adjusted positive electrode profile Rp′ for the battery as pi1, and determine the positive electrode participation end point as pf8. Additionally, the control unit 130 may determine the negative electrode participation start point of the adjusted negative electrode profile Rn′ for the battery as ni1, and determine the negative electrode participation end point as nf8.

The apparatus 100 for managing a battery according to an embodiment of the present disclosure may determine the positive electrode degradation degree and the negative electrode degradation degree of the battery for each of the plurality of sections by determining the adjusted positive electrode profile and the adjusted negative electrode profile for each of the plurality of sections. In other words, the apparatus 100 for managing a battery can estimate the positive electrode degradation degree and the negative electrode degradation degree for each detailed section, so it has an advantage of deriving a diagnostic factor that can more accurately diagnose the state of the battery. In addition, the apparatus 100 for managing a battery has an advantage of more accurately and precisely diagnosing the state of the positive electrode and the negative electrode of the battery through the derived diagnostic factor.

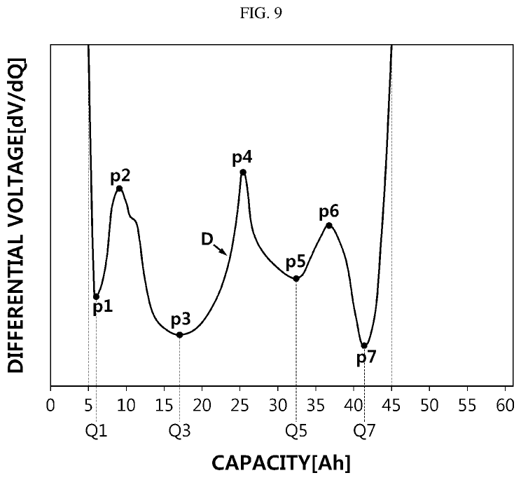

Referring to FIGS. 9 to 11, the profile determining unit 120 may adjust the reference positive electrode profile Rp and the reference negative electrode profile Rn in accordance with an embodiment of the present disclosure.

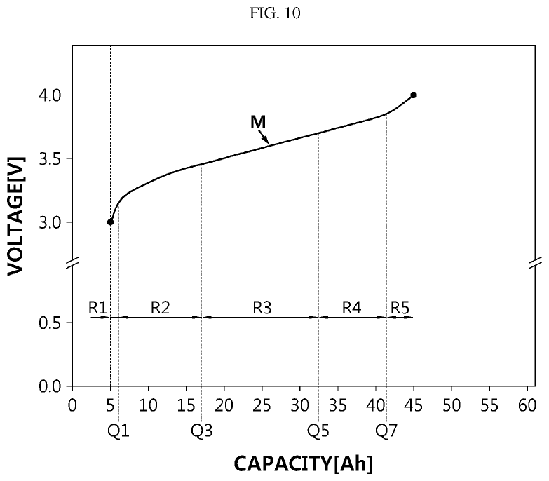

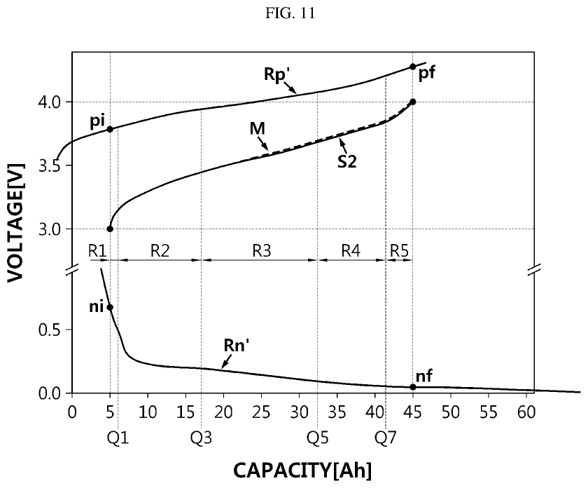

FIG. 9 is a diagram showing a full-cell differential profile D according to an embodiment of the present disclosure. FIG. 10 is a diagram showing the measurement full-cell profile M and a plurality of sections R1 to R5 according to an embodiment of the present disclosure. FIG. 11 is a diagram showing the measurement full-cell profile M and a second comparison full-cell profile S2 according to an embodiment of the present disclosure.

As shown in FIGS. 9-11, the profile determining unit 120 may be configured to divide the measurement full-cell profile M into a plurality of sections R1 to R5 based on the plurality of reference peaks included in the full-cell differential profile D.

In one embodiment, a reference peak may be a peak corresponding to a minimum point of the full-cell differential profile D, as shown in FIG. 9. For example, in accordance with FIG. 9, the plurality of reference peaks may include a first peak p1, a third peak p3, a fifth peak p5, and a seventh peak p7.

In accordance with FIG. 10, the profile determining unit 120 may divide the measurement full-cell profile M into first to fifth sections R1 to R5 according to the plurality of capacities Q1, Q3, Q5, and Q7 corresponding to the reference peaks p1, p3, p5, and p7. Here, the first section R1 is the capacity section of 0 [Ah] to Q1, the second section R2 is the capacity section of Q1 to Q3, and the third section R3 is the capacity section of Q3 to Q5. The fourth section R4 is the capacity section of Q5 to Q7, and the fifth section R5 is the capacity section of Q7 to 45 [Ah].

The profile determining unit 120 may be configured to set a weight for each of the plurality of sections R1 to R5.

In one embodiment, the weight set for each of the plurality of sections R1 to R5 may be a value between 0 and 1, and the total sum of the set weights may be 1.

For example, the control unit 130 may set the weight of the first to fifth sections R1 to R5 to 0.2, respectively.

Additionally or alternatively, the control unit 130 may set the weight of the first to fifth sections R1 to R5 according to the importance of the first to fifth sections R1 to R5. For example, some of the plurality of sections R1 to R5 may be sections that reflect the state of the positive electrode of the battery, and others may be sections that reflect the state of the negative electrode of the battery. The correlation between the plurality of sections R1 to R5 and the importance and states of the first and negative electrodes may be predetermined based one or more statistical analyses performed based on previous experimentation or tests on a plurality of batteries. Accordingly, the control unit 130 may set the importance of the section corresponding to the item to be diagnosed among the plurality of sections R1 to R5 high. Also, the weight for a section with high importance may be set to be larger than the weight for other sections.

In one embodiment, the profile determining unit 120 may be configured to set the weight for the target section including at least one of the plurality of target peaks included in the full-cell differential profile D to be larger than the weight for the remaining sections.

For example, the target peak may be a peak corresponding to the maximum or highest point of the full-cell differential profile D. As shown in FIG. 9, the plurality of target peaks may include the second peak p2, the fourth peak p4, and the sixth peak p6.

The control unit 130 may select at least one of the plurality of target peaks according to the diagnosis object and determine the section including the selected target peak as the target section. For example, if the diagnosis item is the state of the negative electrode, the control unit 130 may determine the second section R2, which includes the second peak p2, as the target section, and set the weight for the second section R2 to be the largest. As another example, when the diagnosis item is the state of the positive electrode, the control unit 130 may determine the fourth section R4, which includes the sixth peak p6, as the target section, and set the weight for the fourth section R4 to be the largest. Again, the correlation between the plurality of sections R1 to R5 and the peaks p1-7 and the importance and states of the first and negative electrodes may be predetermined based one or more statistical analyses performed based on previous experimentation or tests on a plurality of batteries

The profile determining unit 120 may be configured to adjust the reference positive electrode profile Rp and the reference negative electrode profile Rn based on a set weight to correspond to the measurement full-cell profile M.

In one embodiment, the profile determining unit 120 may be configured to generate a second comparison full-cell profile S2 based on the adjusted positive electrode profile Rp′ and the adjusted negative electrode profile Rn′, as shown in FIG. 11.

For example, the profile determining unit 120 may generate a plurality of comparison full-cell profiles by shifting the reference positive electrode profile Rp and the reference negative electrode profile Rn or performing capacity scaling thereto. In accordance with FIG. 11, the profile determining unit 120 may determine the second comparison full-cell profile S2 corresponding to the measurement full-cell profile M based on the adjusted positive electrode profile Rp′ and the adjusted negative electrode profile Rn′. The control unit 130 may determine the positive electrode participation start point of the battery as pi and determine the positive electrode participation end point as pf. Additionally, the control unit 130 may determine the negative electrode participation start point of the battery as ni and determine the negative electrode participation end point as nf.

Additionally, the profile determining unit 120 may be configured to adjust the reference positive electrode profile Rp and the reference negative electrode profile Rn so that the error rate or difference between the comparison full-cell profile S and the measurement full-cell profile M decreases as the set weight of the section increases.

For example, the profile determining unit 120 may specify a comparison full-cell profile with a low error rate (or smallest difference from profile M) in the order of the largest weight among the plurality of sections R1 to R5 of the measurement full-cell profile M among the plurality of comparison full-cell profiles. For example, assuming that hundred comparison full-cell profiles are generated and the target section is the second section R2, the profile determining unit 120 may specify or identify the second comparison full-cell profile S2 with the lowest error rate (or smallest difference) in the second section R2 among the hundred comparison full-cell profiles. Additionally, the profile determining unit 120 may determine the adjusted positive electrode profile Rp′ and the adjusted negative electrode profile Rn′ corresponding to the specified second comparison full-cell profile S2. If there are a plurality of comparison full-cell profiles with the lowest error rate (or smallest difference) in the second section R2, the profile determining unit 120 may specify or identify the second comparison full-cell profile S2 with the lower overall error rate (or smaller difference) for the entire capacity section of the measurement full-cell profile M.

The apparatus 100 for managing a battery according to an embodiment of the present disclosure has an advantage of determining a diagnostic factor that better reflects the state of the battery because it adjusts the reference positive electrode profile Rp and the reference negative electrode profile Rn to correspond to the desired diagnosis item. In other words, because the optimal diagnostic factor corresponding to the diagnosis item can be determined, the state of the battery can be diagnosed more accurately.

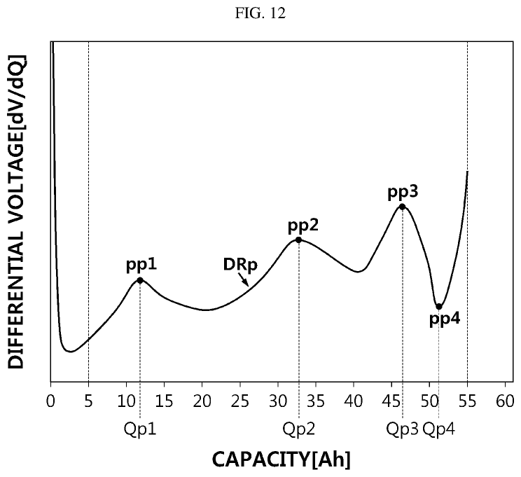

Referring to FIGS. 12 to 15, the profile determining unit 120 may adjust the reference positive electrode profile Rp and the reference negative electrode profile Rn in accordance with an embodiment of the present disclosure.

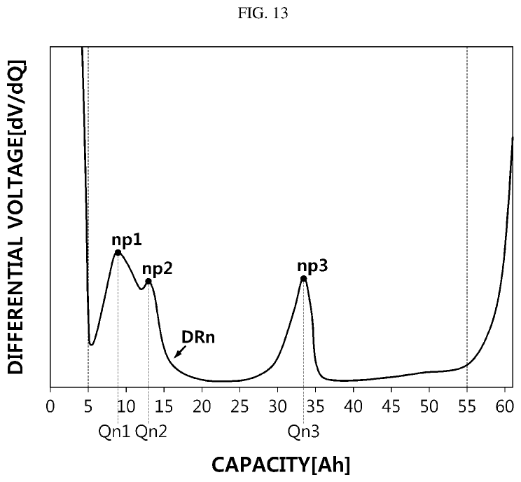

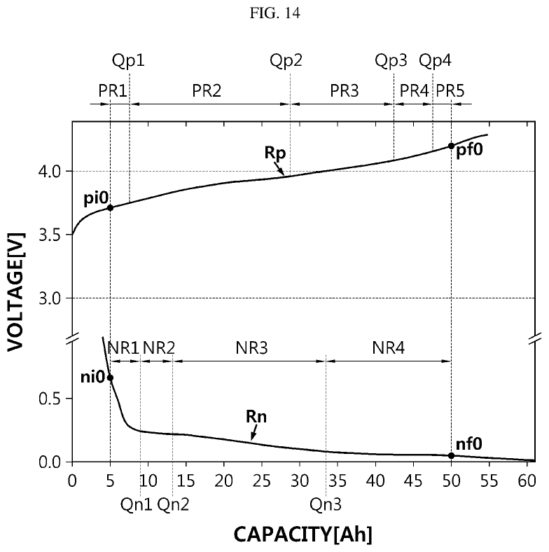

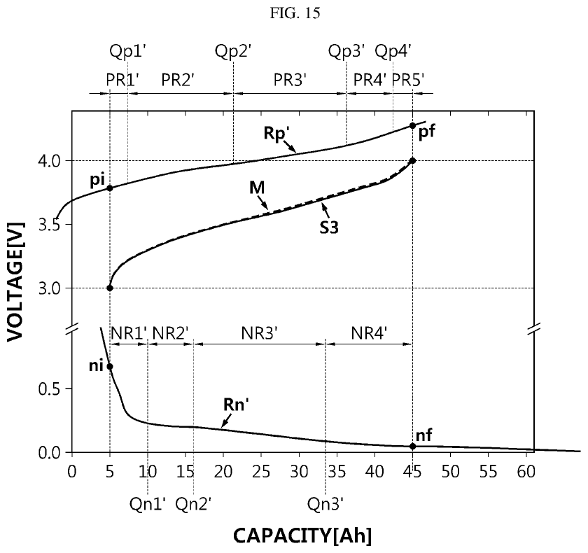

FIG. 12 is a diagram showing a positive electrode differential profile DRp according to an embodiment of the present disclosure. FIG. 13 is a diagram showing a negative electrode differential profile DRn according to an embodiment of the present disclosure. FIG. 14 is a diagram showing a reference positive electrode profile Rp and a reference negative electrode profile Rn according to an embodiment of the present disclosure. FIG. 15 is a diagram showing the measurement full-cell profile M and the third comparison full-cell profile S3 according to an embodiment of the present disclosure.

The profile obtaining unit 110 may be configured to obtain at least one of the positive electrode differential profile DRp corresponding to the reference positive electrode profile Rp and the negative electrode differential profile DRn corresponding to the reference negative electrode profile Rn as an electrode differential profile.

In one embodiment, the positive electrode differential profile DRp is a profile obtained by differentiating the reference positive electrode profile Rp with respect to capacity. The negative electrode differential profile DRn is a profile obtained by differentiating the reference negative electrode profile Rn with respect to capacity.

For example, in the embodiment of FIG. 12, the positive electrode differential profile DRp can be expressed as a two-dimensional X-Y graph with the X-axis set to capacity [Ah] and the Y-axis set to differential voltage [dV/dQ]. In the embodiment of FIG. 13, the negative electrode differential profile DRn can be expressed as a two-dimensional X-Y graph with the X-axis set to capacity [Ah] and the Y-axis set to differential voltage [dV/dQ].

For example, the profile obtaining unit 110 may directly receive the positive electrode differential profile DRp and the negative electrode differential profile DRn of the battery from the outside. That is, the profile obtaining unit 110 can receive information from the outside by wired and/or wirelessly. As another example, the profile obtaining unit 110 may generate a positive electrode differential profile DRp and a negative electrode differential profile DRn based on the reference positive electrode profile Rp and the reference negative electrode profile Rn.

The profile determining unit 120 may be configured to divide a corresponding reference electrode profile among the reference positive electrode profile Rp and the reference negative electrode profile Rn into a plurality of electrode sections based on at least one of a plurality of electrode peaks included in the electrode differential profile

In one embodiment, the positive electrode differential profile DRp may include a plurality of positive electrode peaks, and the negative electrode differential profile DRn may include a plurality of negative electrode peaks.

As shown in FIG. 12, the positive electrode differential profile DRp may include first to fourth positive electrode peaks pp1, pp2, pp3, and pp4. In one embodiment, a positive electrode peak may include a peak corresponding to the maximum (or highest) point in a section of the positive electrode differential profile DRp. A positive electrode peak may include a peak corresponding to the minimum (or lowest) point with the largest capacity value compared to the plurality of peaks (e.g., maximum or highest points in a plurality of sections) of the positive electrode differential profile DRp. The capacity of the first positive electrode peak pp1 is Qp1, the capacity of the second positive electrode peak pp2 is Qp2, the capacity of the third positive electrode peak pp3 is Qp3, and the capacity of the fourth positive electrode peak pp4 is Qp4.

As shown in FIG. 13, the negative electrode differential profile DRn may include first to third negative electrode peaks np1, np2, np3. In one embodiment, the negative electrode peak may include a peak corresponding to the maximum point in a section of the negative electrode differential profile DRn. The capacity of the first negative electrode peak np1 is Qn1, the capacity of the second negative electrode peak np2 is Qn2, and the capacity of the third negative electrode peak np3 is Qn3.

As shown in FIG. 14, the profile determining unit 120 may divide the reference positive electrode profile Rp into first to fifth positive electrode sections PR1 to PR5. The first positive electrode section PR1 may be a capacity section of 5 [Ah] to Qp1, and the second positive electrode section PR2 may be a capacity section of Qp1 to Qp2. The third positive electrode section PR3 may be a capacity section of Qp2 to Qp3, the fourth positive electrode section PR4 may be a capacity section of Qp3 to Qp4, and the fifth positive electrode section PR5 may be a capacity section of Qp4 to 50 [Ah].

Additionally, the profile determining unit 120 may divide the reference negative electrode profile Rn into first to fourth negative electrode sections NR1 to NR4. The first negative electrode section NR1 may be a capacity section of 5 [Ah] to Qn1, and the second negative electrode section NR2 may be a capacity section of Qn1 to Qn2. The third negative electrode section NR3 may be a capacity section of Qn2 to Qn3, and the fourth negative electrode section NR4 may be a capacity section of Qn3 to 50 [Ah].

The profile determining unit 120 may be configured to adjust the reference positive electrode profile Rp and the reference negative electrode profile Rn to correspond to the measurement full-cell profile M while adjusting each of the plurality of electrode sections.

In one embodiment, the profile determining unit 120 may be configured to independently adjust each of the plurality of electrode sections. That is, the profile determining unit 120 may be configured to determine the adjusted positive electrode profile Rp′ and the adjusted negative electrode profile Rn′ corresponding to the measurement full-cell profile M by independently adjusting the change rate of each of the plurality of electrode sections.

The adjusted positive electrode profile Rp′ may be divided into a plurality of adjusted positive electrode sections PR1′ to PR5′, and the adjusted negative electrode profile Rn′ may be be divided into a plurality of adjusted negative electrode sections NR1′ to NR4′. Each of the plurality of adjusted positive electrode sections PR1′ to PR5′ may be obtained by changing each of the plurality of positive electrode sections PR1 to PR5 of the reference positive electrode profile Rp, and each of the plurality of adjusted negative electrode sections NR1′ to NR4′ may be obtained by changing each of the plurality of negative electrode sections NR1 to NR4 of the reference negative electrode profile Rn.

For example, as shown in FIG. 15, the adjusted positive electrode profile Rp′ may be divided into the first to fifth adjusted positive electrode sections PR1′ to PR5′, and each of the first to fifth adjusted positive electrode sections PR1′ to PR5′ may correspond to each of the first to fifth positive electrode sections PR1 to PR5 of the positive electrode profile Rp. The first adjusted positive electrode section PR1′ may be a section obtained by changing the first positive electrode section PR1, and the second adjusted positive electrode section PR2′ may be a section obtained by changing the second positive electrode section PR2. The third adjusted positive electrode section PR3′ may be a section obtained by changing the third positive electrode section PR3, the fourth adjusted positive electrode section PR4′ may be a section obtained by changing the fourth positive electrode section PR4, and the fifth adjusted positive electrode section PR5′ may be a section obtained by changing the fifth positive electrode section PR5. The control unit 130 may determine the positive electrode participation start point pi and the positive electrode participation end point pf of the adjusted positive electrode profile Rp′. Additionally, the control unit 130 may determine the positive electrode change rate ps1 to ps5 for each of the first to fifth adjusted positive electrode sections RP1′ to PR5′. For example, the control unit 130 may determine the ratio of the first adjusted positive electrode section PR1′ to the first positive electrode section PR1 as the positive electrode change rate ps1 to the first adjusted positive electrode section PR1′. That is, the control unit 130 may determine the positive electrode change rates ps1 to ps5 to the plurality of adjusted positive electrode sections RP1′ to PR5′ by calculating the change rate of the adjusted positive electrode sections RP1′ to PR5′ with respect to the positive electrode sections PR1 to PR5. Likewise, the control unit 130 may determine the positive electrode change rates ps2 to ps5 for the second to fifth adjusted positive electrode sections PR2′ to PR5′.

Likewise, as shown in FIG. 15, the adjusted negative electrode profile Rn′ may be divided into first to fourth adjusted negative electrode sections NR1′ to NR4′, and each of the first to fourth adjusted negative electrode sections NR1′ to NR4′ may correspond to each of the first to fourth negative electrode sections NR1 to NR4 of the reference negative electrode profile Rn. The first adjusted negative electrode section NR1′ may be a section obtained by changing the first negative electrode section NR1, and the second adjusted negative electrode section NR2′ may be a section obtained by changing the second negative electrode section NR2. The third adjusted negative electrode section NR3′ may be a section obtained by changing the third negative electrode section NR3, and the fourth adjusted negative electrode section NR4′ may be a section obtained by changing the fourth negative electrode section NR4. The control unit 130 may determine the negative electrode participation start point ni and the negative electrode participation end point nf of the adjusted negative electrode profile Rn′. Additionally, the control unit 130 may determine the negative electrode change rate ns1 to ns4 for each of the first to fourth adjusted negative electrode sections NR1′ to NR4′. For example, the control unit 130 may determine the ratio of the first adjusted negative electrode section NR1′ to the first negative electrode section NR1 as the negative electrode change rate ns1 to the first adjusted negative electrode section NR1′. That is, the control unit 130 may determine the negative electrode change rate for the plurality of adjusted negative electrode sections NR1′ to NR4′ by calculating the change rate of the adjusted negative electrode sections NR1′ to NR4′ with respect to the negative electrode sections NR1 to NR4. Likewise, the control unit 130 may determine the negative electrode change rates ns2 to ns4 for the second to fourth adjusted negative electrode sections NR2′ to NR4′.

The profile determining unit 120 may determine a third comparison full-cell profile S3 corresponding to the measurement full-cell profile M based on the adjusted positive electrode profile Rp′ and the adjusted negative electrode profile Rn′. In accordance with FIG. 15, the control unit 130 may determine the positive electrode participation start point of the battery as pi and determine the positive electrode participation end point as pf. Additionally, the control unit 130 may determine the negative electrode participation start point of the battery as ni and determine the negative electrode participation end point as nf.

In other words, when the positive electrode differential profile DRp is included in the electrode differential profile, the profile determining unit 120 may be configured to divide the reference positive electrode profile Rp into a plurality of positive electrode sections based on at least one of the plurality of positive electrode peaks included in the positive electrode differential profile DRp. In addition, when the negative electrode differential profile DRn is included in the electrode differential profile, the profile determining unit 120 may be configured to divide the reference negative electrode profile Rn into a plurality of negative electrode sections based on at least one of the plurality of negative electrode peaks included in the negative electrode differential profile DRn. FIGS. 12 to 14 show both the positive electrode differential profile DRp and the negative electrode differential profile DRn that are included in the electrode differential profile so that the reference positive electrode profile Rp may be divided into a plurality of positive electrode sections and the reference negative electrode profile Rn may be divided into a plurality of negative electrode sections in accordance with an embodiment of the present disclosure. However, the positive electrode differential profile DRp or the negative electrode differential profile DRn may be included in the electrode differential profile in accordance with embodiments of the present disclosure.

The apparatus 100 for managing a battery according to an embodiment of the present disclosure may determine an adjusted positive electrode profile and an adjusted negative electrode profile by adjusting the plurality of positive electrode sections and/or the plurality of negative electrode sections. In other words, the apparatus 100 for managing a battery has an advantage of determining detailed diagnostic factors for the battery. Therefore, based on the diagnostic factors, the state of the battery can be diagnosed in more detail and accurately.

The apparatus 100 for managing a battery according to the present disclosure may be applied to a battery management system (BMS). For example, a BMS according to the present disclosure may include the above-described apparatus 100 for managing a battery. In this configuration, at least some of the components of the apparatus 100 for managing a battery may be implemented by supplementing or adding functions of components included in a conventional BMS. For example, the profile obtaining unit 110, the profile determining unit 120, the control unit 130 and the storage unit 140 of the apparatus 100 for managing a battery may be implemented as components of a BMS.

Additionally, the apparatus 100 for managing a battery according to the present disclosure may be provided in a battery pack. That is, the battery pack according to the present disclosure may include the above-described apparatus 100 for managing a battery and at least one battery cell. Additionally, the battery pack may further include electrical components (relays, fuses, etc.) and a case.

FIG. 16 is a diagram showing an exemplary configuration of the battery pack including according to an embodiment of the present disclosure.

The positive electrode terminal of a battery 10 may be connected to a positive electrode terminal P+ of a battery pack 1, and a negative electrode terminal of the battery 10 may be connected to a negative electrode terminal P− of the battery pack 1.

A measuring unit 20 may be connected to the positive electrode terminal and the negative electrode terminal of the battery 10. Additionally, the measuring unit 20 may be configured to measure the voltage of the battery 10 by measuring the positive electrode potential and the negative electrode potential of the battery 10 and calculating the difference between the positive electrode potential and the negative electrode potential.

In addition, the measuring unit 20 may be connected to a current measurement unit A. For example, the current measurement unit A may be an ammeter or a shunt resistor that may be configured to measure the charging current and discharging current of the battery 10. The measuring unit 20 may be configured to calculate the charging amount by measuring the charging current of the battery 10 using the current measurement unit A. Additionally, the measuring unit 20 may be configured to calculate the discharge amount by measuring the discharge current of the battery 10 through the third sensing line SL3.

For example, the information about the voltage and capacity of the battery 10 measured by the measuring unit 20 may be transmitted to the profile obtaining unit 110. Additionally, the profile obtaining unit 110 may be configured to directly generate a measurement full-cell profile M based on the received information about the voltage and capacity.

For example, the information about the voltage and capacity of the battery 10 measured by the measuring unit 20 may be stored in the storage unit 140. When the charging or discharging of the battery 10 is completed, the profile obtaining unit 110 may access the storage unit 140 to obtain the measurement full-cell profile M.

For example, the measuring unit 20 may be configured to directly generate a measurement full-cell profile M based on the measured information about the voltage and capacity of the battery 10. In this case, the generated measurement full-cell profile M may be transmitted to the profile obtaining unit 110 and also be stored in the storage unit 140.

A charge/discharge device or load may be connected to the positive electrode terminal P+ and the negative electrode terminal P− of the battery pack 1.

FIG. 17 is a diagram schematically showing a vehicle 1700 according to an embodiment of the present disclosure.

Referring to FIG. 17, the battery pack according to an embodiment of the present disclosure may be included in a vehicle 1700 such as an electric vehicle (EV) or a hybrid vehicle (HV). In addition, the battery pack 1710 may drive the vehicle 1700 by supplying power to a motor through an inverter included in the vehicle 1700. Here, the battery pack 1710 may include the apparatus 100 for managing a battery in accordance with embodiments of the present disclosure. That is, the vehicle 1700 may include the apparatus 100 for managing a battery in accordance with the embodiments of the present disclosure. For example, the apparatus 100 for managing a battery may be an on-board diagnostic device included in the vehicle 1700.

Computer-readable media having stored thereon instructions configured to cause one or more computers to perform any of the methods described herein are also described. A computer readable medium may include volatile or nonvolatile, removable or nonremovable media implemented in any method or technology capable of storing information, such as computer readable instructions, data structures, program modules, or other data. In general, functionality of computing devices described herein may be implemented in computing logic embodied in hardware or software instructions, which can be written in a programming language, such as C, C++, COBOL, JAVA™, PHP, Perl, Python, Ruby, HTML, CSS, JavaScript, VBScript, ASPX, Microsoft .NET™ languages such as C#, and/or the like. Computing logic may be compiled into executable programs or written in interpreted programming languages. Generally, functionality described herein can be implemented as logic modules that can be duplicated to provide greater processing capability, merged with other modules, or divided into sub modules. The computing logic can be stored in any type of computer readable medium (e.g., a non-transitory medium such as a memory or storage medium) or computer storage device and be stored on and executed by one or more general purpose or special purpose processors, thus creating a special purpose computing device configured to provide functionality described herein.

The applications and the functionalities disclosed in the foregoing and following embodiments may be achieved by programming the apparatus 100 or pack 1 (or system 1) in accordance with the description provided in connection with, for example, FIGS. 1-17. That is, the apparatus 100 system 1 in the foregoing and following embodiments may utilize, for example, computer-readable media having stored thereon instructions configured to cause one or more computers or processors to perform any of the methods described herein.

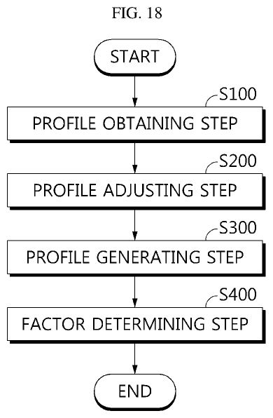

FIG. 18 is a diagram schematically showing a method for executing functions and methods for managing a battery based on the apparatus 100 or system 1 disclosed in connection with FIGS. 1-17, according to aspects of the present disclosure.

Referring to FIG. 18, the method for managing a battery may include a profile obtaining step (S100), a profile adjusting step (S200), a profile generating step (S300), and a factor determining step (S400).

Preferably, each step of the method for managing a battery may be performed by the apparatus 100 for managing a battery. Hereinafter, for convenience of explanation, content that overlaps with the content described above will be omitted or briefly described.

The profile obtaining step (S100) may be a step of obtaining a measurement full-cell profile M indicating the corresponding relationship between the voltage and capacity of the battery, and can be performed by the profile obtaining unit 110.

For example, the profile obtaining unit 110 may directly receive the measurement full-cell profile M of the battery from the outside. That is, the profile obtaining unit 110 can obtain the measurement full-cell profile M by being connected to the outside by wired and/or wirelessly and receiving the measurement full-cell profile M.

For example, the profile obtaining unit 110 may receive battery information about the voltage and capacity of the battery. Also, the profile obtaining unit 110 may be configured to obtain the measurement full-cell profile M by generating the measurement full-cell profile M based on the received battery information.

In one embodiment, the profile obtaining unit 110 may obtain a first profile being based on a voltage value of the battery 10. The first profile may be the measurement full-cell profile M.

In one embodiment, the profile obtaining unit 110 may be configured to obtain at least one of a first differential profile corresponding to a first reference profile or a second differential profile corresponding to a second reference profile. The first reference profile may be a reference positive electrode profile Rp, and the second reference profile may be a reference negative electrode profile Rn. The profile adjusting step (S200) may be a step of determining whether or not to divide the measurement full-cell profile M into a plurality of sections according to a predetermined reference, and adjusting the preset reference positive electrode profile Rp and the reference negative electrode profile Rn to correspond to the measurement full-cell profile M or the plurality of sections depending on whether the measurement full-cell profile M is divided, and can be performed by the profile determining unit 120.

In one embodiment, the profile determining unit 120 may determine whether a first condition is satisfied. Upon determining the first condition is satisfied, the profile determining unit 120 may divide the first profile into a plurality of section. The first condition may comprise information or data relating to voltage-capacity characteristics of the battery 10. For example, the data may be one or more differential voltage associated with the battery 10. The first condition may be satisfied based on determining a presence of the data or based on receiving one or more commands from an operator of the apparatus 100 or from an external source coupled to the apparatus 100.

In one embodiment, the profile obtaining unit 110 may be configured to, upon determining the first condition is satisfied, obtain a differential profile corresponding to the first profile. Further, the profile determining unit may be configured to divide the first profile into the plurality of sections based on a rate of voltage change in the differential profile. For example, the rate of voltage change may be a differential voltage.

In one embodiment, the profile determining unit 120 may divide the first profile into the plurality of sections based on capacity values associated with the differential profile.

In one embodiment, when the measurement full-cell profile M is divided into a plurality of sections, the profile determining unit 120 may adjust a reference positive electrode profile Rp and a reference negative electrode profile Rn to correspond to each section of the measurement full-cell profile M. Here, when the plurality of sections are divided in the number of n, the reference positive electrode profile Rp and the reference negative electrode profile Rn may be adjusted for each of the n sections. For example, in accordance with FIG. 8, the profile determining unit 120 may adjust the reference positive electrode profile Rp and the reference negative electrode profile Rn to correspond to each of the first to eighth sections R1 to R8.

In another embodiment, when the measurement full-cell profile M is not divided into a plurality of sections, the profile determining unit 120 may adjust the reference positive electrode profile Rp and the reference negative electrode profile Rn to correspond to the entire section of the measurement full-cell profile M. Here, one adjustment result for the reference positive electrode profile Rp and the reference negative electrode profile Rn can be derived. For example, in the embodiment of FIG. 11, the profile determining unit 120 may determine the target section of the measurement full-cell profile M, and adjust the reference positive electrode profile Rp and the reference negative electrode profile Rn so that the error rate in the target section is lowest. As another example, in the embodiment of FIG. 15, the profile determining unit 120 may divide the reference positive electrode profile Rp and/or the reference negative electrode profile Rn into a plurality of electrode sections, and adjust each of the plurality of electrode sections to correspond to the measurement full-cell profile M.

The profile generating step (S300) may be a step of generating an adjusted positive electrode profile Rp′ and an adjusted negative electrode profile Rn′ according to the adjustment result, and may be performed by the profile determining unit 120.

For example, in accordance with FIG. 8, the profile determining unit 120 may determine first to eighth adjusted positive electrode profiles Rp1′ to Rp8′ and first to eighth adjusted negative electrode profiles Rn1′ to Rn8′ for the first to eighth sections R1 to R8. The first comparison full-cell profile S1 may be determined based on the plurality of adjusted positive electrode profiles Rp1′ to Rp8′ and the plurality of adjusted negative electrode profiles Rn1′ to Rn8′.

For example, in the embodiment of FIG. 11, the profile determining unit 120 may determine the adjusted positive electrode profile Rp′ and the adjusted negative electrode profile Rn′ that have the lowest error rate for the determined target section. The second comparison full-cell profile S2 may be determined based on the adjusted positive electrode profile Rp′ and the adjusted negative electrode profile Rn′.

For example, in the embodiment of FIG. 15, the profile determining unit 120 may determine the adjusted positive electrode profile Rp′ and the adjusted negative electrode profile Rn′ by adjusting the first to fifth positive electrode sections PR1 to PR5 and the first to fourth negative electrode sections NR1 to NR4, respectively. The third comparison full-cell profile S3 may be determined based on the adjusted positive electrode profile Rp′ and the adjusted negative electrode profile Rn′.

In one embodiment, a first reference profile may be adjusted based on the first profile to generate a second profile. The first reference profile may be a reference positive electrode profile Rp, and the second profile may be an adjusted positive electrode profile Rp′. Additionally or alternatively, a second reference profile may be adjusted based on the first profile to generate a third profile. The second reference profile may be a reference negative electrode profile Rn, and the third profile may be an adjusted negative electrode profile Rn′. Additionally or alternatively, the profile determining unit 120 may be configured to generate the second profile and the third profile based on the plurality of sections.

In one embodiment, the profile determining unit 120 may be configured to generate a plurality of adjusted second profiles. The adjusted second profiles may be a plurality of adjusted positive electrode profiles Rp′. A first point value of a first one of the plurality of adjusted second profiles may correspond to a second point value of a second one of the plurality of adjusted second profiles adjacent to the first one of the plurality of adjusted second profiles. For example, the first point value may be pf1 and the second point value may be pi2, for example, as shown in FIG. 8. The profile determining unit 120 may be configured to generate a plurality of adjusted third profiles. The plurality of adjusted third profiles may be a plurality of adjusted negative electrode profiles Rn′. A third point value of a first one of the plurality of adjusted third profiles may correspond to a fourth point value of a second one of the plurality of adjusted third profile adjacent to the third one of the plurality of adjusted third profiles. For example, the first point value may be nf1 and the second point value may be ni2, for example, as shown in FIG. 8.

In one embodiment, the profile determining unit 120 may be configured to determine an adjustment factor for each of the plurality of sections. Additionally, the profile determining unit 120 may be configured to adjust the first reference profile and the second reference profile based on the adjustment factor. For example, the adjustment factor may be a numerical weight set for each of the plurality of sections. The adjustment factor may be a value between 0 and 1, but is not limited thereto.

In one embodiment, the profile determining unit may be configured to determine a first adjustment factor for a first section of the plurality of sections, and a second adjustment factor for a second section of the plurality of sections. The first section of the plurality of sections may be a target section in the differential profile corresponding to the first profile, and the first adjustment factor may be greater than the second adjustment factor. For example, the target section may be a section having the most importance among the plurality of sections or a particular desired state of the positive or negative electrodes. In one embodiment, the profile determining unit 120 may be configured to generate a comparison profile based on the second profile and the third profile. The first reference profile and the second reference profile are adjusted to generate the comparison profile with minimized profile characteristic difference from the first profile. For example, a plurality of comparison profiles may be generated by adjusting the first reference profile and the second profile multiple times. The profile determining unit 129 may compare the generated comparison profiles with the first profile to identify a comparison profile that matches the first profile mostly closely. For example, data or a graph of the comparison profile that may closely overlap with the data or graph of the first profile may be determined to have minimized profile characteristic difference.

In one embodiment, the profile determining unit 120 may be configured to divide at least one of the first reference profile or the second reference profile into a plurality of electrode sections based on capacity values associated with a corresponding differential profile. The profile determining unit 120 may adjust at least one of the first reference profile or the second reference profile to correspond to the first profile by adjusting at least one of the plurality of electrode sections.

In one embodiment, the profile determining unit 120 may be configured to adjust each of the plurality of electrode sections. For example, the plurality of electrodes sections may be PR1-PR5 and/or NR1-NR4, as shown in FIG. 14, but are not limited thereto.

In one embodiment, the profile determining unit may be configured to divide the first reference profile into a plurality of first electrode sections based on at least one of peaks of the first differential profile. The profile determining unit may be configured to divide the second reference profile into a plurality of second electrode sections based on at least one of peaks in the second differential profile. The peaks of the first differential profile and the peaks of the second differential profile may comprise, for example, pp1-pp4 in FIG. 12 and np1-np3 in FIG. 13, respectively, but are not limited thereto.

The factor determining step (S400) may be a step of determining a positive electrode factor for the battery from the adjusted positive electrode profile Rp′ and a negative electrode factor for the battery from the adjusted negative electrode profile Rn′, and can be performed by the control unit 130.

For example, the control unit 130 may determine the positive electrode participation start point, the positive electrode participation end point, and the positive electrode change rate in the adjusted positive electrode profile Rp′, and determine the negative electrode participation start point, the negative electrode participation end point, and the negative electrode change rate in adjusted negative electrode profile Rn′.

In one embodiment, the control unit 130 may be configured to determine a diagnostic factor based on the second profile. The diagnostic factors may include, for example, a positive electrode factor and a negative electrode factor. The diagnostic factor may indicate a current state of the battery. The positive electrode factor may include a change rate ps of the positive electrode, but is not limited thereto. The negative electrode factor may include a change rate ns of the negative electrode, but is not limited thereto.

The steps of the methods described in the foregoing embodiments improves the conventional battery managing technology by providing, among other things, the apparatus 100 for managing a battery that can be utilized in various applications, for example, but not limited to, battery pack, electric vehicle, etc. That is, the apparatus 100, system 1, processes, and methods of the foregoing embodiments are directed to an improvement in the field of battery technology and are practically applicable to the field of battery management by utilizing the apparatus 100 or system 1, as well the methods, processes, and functionality disclosed in connection with FIGS. 1-18 of the present disclosure. Accordingly, the apparatus 100, system 1, as well as the individual or combination of multiples steps of the methods, process, and functionality of the present disclosure significantly improve diagnosing the state of battery and/or battery electrodes by deriving diagnostic factor by estimating battery and electrode states in a plurality of sections in battery profiles.

The embodiments of the present disclosure described above may not be implemented only through an apparatus and a method, but may be implemented through a program that realizes a function corresponding to the configuration of the embodiments of the present disclosure or a recording medium on which the program is recorded. The program or recording medium may be easily implemented by those skilled in the art from the above description of the embodiments.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

Additionally, many substitutions, modifications and changes may be made to the present disclosure described hereinabove by those skilled in the art without departing from the technical aspects of the present disclosure, and the present disclosure is not limited to the above-described embodiments and the accompanying drawings, and each embodiment may be selectively combined in part or in whole to allow various modifications.

### EXPLANATION OF REFERENCE SIGNS

1: battery pack
10: battery
20: measuring unit
100: apparatus for managing a battery
110: profile obtaining unit
120: profile determining unit
130: control unit
140: storage unit
1700: vehicle
1710: battery pack

What is claimed is:

1. An apparatus for managing a battery, comprising:
a profile obtaining unit configured to obtain a first profile, the first profile being based on a voltage value of the battery and a capacity value of the battery;
a profile determining unit configured to:
determine whether a first condition is satisfied;
upon determining the first condition is satisfied, divide the first profile into a plurality of sections;
adjusting a first reference profile based on the first profile or the plurality of section to generate a second profile; and
a control unit configured to determine a diagnostic factor based on the second profile.

2. The apparatus according to claim 1, wherein the profile determining unit is configured to adjust a second reference profile based on the first profile or the plurality of sections to generate a third profile.

3. The apparatus according claim 1, wherein the second profile is an adjusted positive electrode profile.

4. The apparatus according to claim 2, wherein the third profile is an adjusted negative electrode profile.

5. The apparatus according to claim 1, wherein the profile obtaining unit is further configured to, upon determining the first condition is satisfied, obtain a differential profile corresponding to the first profile, and
wherein the profile determining unit is configured to divide the first profile into the plurality of sections based on a rate of voltage change in the differential profile.

6. The apparatus according to claim 5, wherein the profile determining unit is configured to divide the first profile into the plurality of sections based on capacity values associated with the differential profile.

7. The apparatus according to claim 2, wherein the profile determining unit is configured to generate the second profile and the third profile based on the plurality of sections.

8. The apparatus according to claim 7, wherein the profile determining unit is configured to generate a plurality of adjusted second profiles,
wherein a first point value of a first one of the plurality of adjusted second profiles corresponds to a second point value of a second one of the plurality of adjusted second profiles adjacent to the first one of the plurality of adjusted second profiles,
wherein the profile determining unit is configured to generate a plurality of adjusted third profiles, and
wherein a third point value of the first one of the plurality of adjusted third profiles corresponds to a fourth point value of a second one of the plurality of adjusted third profiles adjacent to the first one of the plurality of adjusted third profiles.

9. The apparatus according to claim 2, wherein the profile determining unit is configured to:
determine an adjustment factor for each of the plurality of sections; and
adjust the first reference profile and the second reference profile based on the adjustment factor.

10. The apparatus according to claim 9, wherein the profile determining unit is configured to determine a first adjustment factor for a first section of the plurality of sections and a second adjustment factor for a second section of the plurality of sections,
wherein the first section of the plurality of sections is a target section in the differential profile corresponding to the first profile, and
wherein the first adjustment factor is greater than the second adjustment factor.

11. The apparatus according to claim 10, wherein the profile determining unit is configured to generate a comparison profile based on the second profile and the third profile, and
wherein the first reference profile and the second reference profile are adjusted to generate the comparison profile with minimized profile characteristic difference from the first profile.

12. The apparatus according to claim 2, wherein the profile obtaining unit is configured to obtain at least one of a first differential profile corresponding to the first reference profile or a second differential profile corresponding to the second reference profile, and
wherein the profile determining unit is configured to:
divide at least one of the first reference profile or the second reference profile into a plurality of electrode sections based on capacity values associated with a corresponding differential profile; and
adjust at least one of the first reference profile or the second reference profile to correspond to the first profile by adjusting at least one of the plurality of electrode sections.

13. The apparatus according to claim 12, wherein the profile determining unit is configured to adjust each of the plurality of electrode sections.

14. The apparatus for managing a battery according to claim 12, wherein the profile determining unit is configured to divide the first reference profile into a plurality of first electrode sections based on at least one of peaks of the first differential profile, and
wherein the profile determining unit is configured to divide the second reference profile into a plurality of second electrode sections based on at least one of peaks in the second differential profile.

15. A battery pack, comprising the apparatus for managing the battery according to claim 1.

16. A vehicle, comprising the apparatus for managing the battery according to claim 1.

17. A method for managing a battery, comprising:
obtaining a first profile, the first profile being based on a voltage value of the battery and a capacity value of the battery;
determining whether a first condition is satisfied;
upon determining the first condition is satisfied, dividing the first profile into a plurality of sections;
adjusting a first reference profile based on the first profile to generate a second profile; and
determining a diagnostic factor based on the second profile.

18. The method according to claim 17, further comprising adjusting a second reference profile based on the first profile or the plurality of sections to generate a third profile.

19. The method according claim 17, wherein the second profile is a positive electrode profile.

20. The method according to claim 18, wherein the third profile is a negative electrode profile.
